(19) United States
(12) Patent Application Publication
(10) Pub. No.: US 2014/0162191 A1
(43) Pub. Date: Jun. 12, 2014

(54) DRAWING APPARATUS, AND METHOD OF MANUFACTURING ARTICLE

(71) Applicant: CANON KABUSHIKI KAISHA, Tokyo (JP)

(72) Inventor: Hirohito Ito, Utsunomiya-shi (JP)

(73) Assignee: CANON KABUSHIKI KAISHA, Tokyo (JP)

(21) Appl. No.: 14/090,982

(22) Filed: Nov. 26, 2013

(30) Foreign Application Priority Data
Nov. 30, 2012 (JP) 2012-263514

(51) Int. Cl. G03F 7/20; B41J 2/47

(52) U.S. Cl. CPC G03F 7/2059; B41J 2/473
USPC 430/296; 347/237

(57) ABSTRACT

A drawing apparatus, that performs drawing on a substrate with charged particle beams based on first image data associated with a first grid, includes a blanker array including a plurality of columns each including a plurality of blankers, a scanning deflector configured to deflect at least one of the charged particle beams that has not been blanked by the blanker array to cause the deflected beam to scan the substrate in a scan direction, a drive circuit configured to sequentially drive the blanker array with respect to each of the columns periodically to define a second grid on the substrate that is displaced from the first grid in the scan direction, and a controller configured to generate second image data on the second grid by performing interpolation processing on the first image data and to control the drive circuit based on the second image data.

### BACKGROUND OF THE INVENTION

1. Field of the Invention

The present invention relates to a drawing apparatus that performs drawing on a substrate with a plurality of charged particle beams and a method of manufacturing an article using the drawing apparatus.

2. Description of the Related Art

As a drawing apparatus used for manufacturing devices including semiconductor integrated circuits, a drawing apparatus that performs drawing on a substrate with a plurality of charged particle beams has been proposed (Japanese Patent Application Laid-Open No. 9-7538). In such a drawing apparatus, drawing may be performed by main scanning of each charged particle beam and sub scanning of a substrate.

Increase of the number of charged particle beams used for drawing can be a measure to improve throughput of such a drawing apparatus. However, increase of the number of charged particle beams requires increase of the number of wirings of a blanker array for individually blanking the charged particle beams, which makes it difficult to perform wiring and mounting the blanker array. Therefore, Proc. of SPIE Vol. 7637,76371Z (2010) discusses a method whereby a control signal line is shared by each one of a plurality of columns that is arranged in a blanker, each column is sequentially switched using the control signal lines, and deflectors in each column is sequentially applied with voltage by instruction values for the respective columns.

In a drawing apparatus, a pattern to be drawn can be formed by grid points or pixels. A dose (i.e., amount of exposure) can be controlled by setting beam irradiation time for each grid point to either one of binary values (i.e., zero or a specified value) and changing arrangement of grid points for which beam irradiation time is set to the specified value. When the method of Proc. of SPIE Vol. 7637,76371Z (2010) (referred to as an active matrix driving system, hereinafter) is employed in a drawing apparatus with a spatial modulation system, positional deviation (displacement) of grid points in a main scan direction is caused between column units of sequentially switched blankers. As a result, positional deviation or a blur (thinning of a line width, for example) is caused in a drawn pattern, accuracy of drawing with respect to drawing data is deteriorated, and yields may be decreased.

### SUMMARY OF THE INVENTION

The present invention is beneficial for addressing the above-noted problems with the related art and comprises, for example, a drawing apparatus which is advantageous in fidelity with respect to drawing data while employing the active matrix driving system for a blanker array.

According to an aspect of the present invention, a drawing apparatus, that performs drawing on a substrate with a plurality of charged particle beams based on first image data associated with a first grid, includes a blanker array including a plurality of columns each including a plurality of blankers, a scanning deflector configured to deflect at least one of the charged particle beams that has not been blanked by the blanker array to cause the deflected beam to scan the substrate in a scan direction, a drive circuit configured to sequentially drive the blanker array with respect to each of the plurality of columns periodically to define a second grid on the substrate that is displaced from the first grid in the scan direction, and a controller configured to generate second image data on the second grid by performing interpolation processing on the first image data associated with the first grid and to control the drive circuit based on the second image data.

Further features of the present invention will become apparent from the following description of exemplary embodiments with reference to the attached drawings.

### BRIEF DESCRIPTION OF THE DRAWINGS

FIG. 1 illustrates a configuration example of a drawing apparatus.

FIG. 2 illustrates a raster scan system drawing method.

FIG. 3 is a view for describing a positional relationship among a plurality of stripe drawing areas.

FIG. 4 illustrates a configuration example of a drive circuit of a blanker array.

FIG. 5 illustrates another configuration example of a drive circuit of a blanker array.

FIGS. 6A, 6B, 6C, 6D, 6E, and 6F are views for describing a drawing method of spatial modulation system.

FIGS. 7A, 7B, and 7C illustrate examples of arrangement of scanning grids (i.e., pixels) on a substrate.

FIG. 8 illustrates a data flow of the drawing apparatus.

FIG. 9A and FIG. 9B respectively illustrate a configuration example and a flowchart for generating control data according to a first exemplary embodiment.

FIG. 10A and FIG. 10B respectively illustrate a configuration example and a flowchart for generating control data according to a second exemplary embodiment.

FIG. 11A and FIG. 11B respectively illustrate a configuration example and a flowchart for generating control data according to a third exemplary embodiment.

FIG. 12A and FIG. 12B respectively illustrate a configuration example and a flowchart for generating control data according to a fourth exemplary embodiment.

### DESCRIPTION OF THE EMBODIMENTS

Various exemplary embodiments, features, and aspects of the invention will be described in detail below with reference to the drawings.

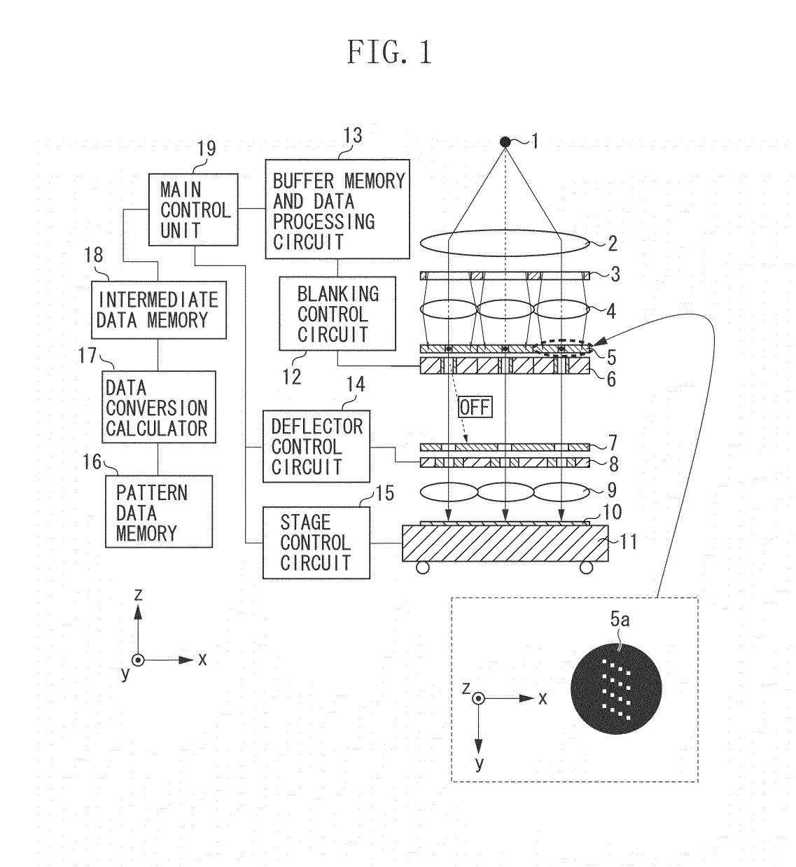

FIG. 1 illustrates a configuration example of a drawing apparatus according to a first exemplary embodiment of the present invention. In FIG. 1, an electron source 1 may be a thermionic electron source including such as LaB or BaO/W (i.e., a dispenser cathode) as an electron emitting member. A collimator lens 2 may be an electrostatic lens that converges an electron beam by an electric field. The collimator lens 2 changes an electron beam emitted from the electron source 1 into a substantially parallel electron beam. The drawing apparatus of this exemplary embodiment draws a pattern on a substrate using a plurality of electron beams. However, charged particle beams such as ion beams other than the electron beams can be used, and thus the drawing apparatus of this exemplary embodiment may be generalized to a drawing apparatus that draws a pattern on a substrate with a plurality of charged particle beams.

An aperture array 3 (i.e., an aperture array member) includes apertures arranged two-dimensionally. In a condenser lens array 4, electrostatic condenser lenses having identical optical power are arranged two-dimensionally. A pattern aperture array 5 (i.e., a pattern aperture array member) includes pattern aperture arrays (i.e., sub arrays) that specify (determine) a shape of electron beams corresponding to respective condenser lenses. An arrangement 5a is an example arrangement (i.e., an arrangement viewed from Z-axis in the drawing) of a plurality of pattern apertures in a part of the pattern aperture array 5 surrounded by a dashed line (i.e., a sub array).

The aperture array 3 splits the substantially parallel electron beam that has passed through the collimator lens 2 into a plurality of electron beams. The split electron beams illuminate corresponding apertures of the pattern aperture array 5 through corresponding condenser lenses of the condenser lens array 4. The aperture array 3 has a function to determine a range of the illumination.

A blanker array 6 includes a plurality of blankers which is arranged in a plurality of rows. The blankers are electrostatic blankers (i.e., electrode pairs), which can be separately driven, corresponding to the respective apertures of the pattern aperture array 5. In FIG. 1, only one blanker is illustrated in each sub array for simplification. A blanking aperture array 7 includes blanking apertures (each of which has one aperture), which are arranged corresponding to respective condenser lenses. A deflector array 8 (also referred to as a scanning deflector) deflects all charged particle beams that have not been blanked by the blanker array 6 and makes the deflected beams scan on a wafer in a scan direction. The deflector array 8 includes deflectors, which are arranged corresponding to the respective condenser lenses. The deflectors deflect the electron beams in a predetermined direction (i.e., a main scan direction) corresponding to the respective condenser lenses. An objective lens array 9 includes electrostatic objective lenses, which are arranged corresponding to the respective condenser lenses. On a wafer 10 (i.e., a substrate), drawing (i.e., exposure) is performed. The components labeled with reference numerals 1 to 9 are included in an electron (i.e., a charged particle) optical system.

The pattern aperture array 5 is illuminated by electron beams, and electron beams from the respective apertures of the pattern aperture array 5 pass through the corresponding blankers, blanking apertures, deflectors, and objective lenses. Thus, the electron beams are reduced 100 times, for example, and projected onto the wafer 10. A surface where the pattern apertures are arranged is an object plane, and an upper surface of the wafer 10 is an image plane.

The electron beams from the apertures of the illuminated pattern aperture array 5 can be shielded by the blanking aperture array 7 by control of the corresponding blanker. In other words, incident electron beams onto the wafer 10 can be switched. Simultaneously, the incident electron beams onto the wafer 10 scan on the wafer 10 with an identical amount of deflection using the deflector array 8.

The electron source 1 is set to form an image on the blanking aperture through the collimator lens 2 and the condenser lens where the size of the image is bigger than the apertures of the blanking aperture. Therefore, a half angle of the electron beams on the wafer 10 is determined by the apertures of the blanking aperture. In addition, since the apertures of the blanking aperture array 7 are arranged at front focal positions of the corresponding objective lenses, a principal ray of the plurality of electron beams from the plurality of pattern apertures of the sub array is substantially vertically incident onto the wafer 10 thereto. Therefore, even when an upper surface of the wafer 10 is displaced upward or downward, the displacement of electron beams in a horizontal plane is minute.

An X-Y stage 11 (also referred to simply as a stage) is movable within an X-Y plane (horizontal plane) that holds the wafer 10 and is vertical to an optical axis. The X-Y stage 11 includes an electrostatic chuck (not illustrated) holding (attracting) the wafer 10, an aperture pattern into which the electron beams are incident, and a detector (not illustrated) that detects positions of the electron beams.

A blanking control circuit 12 individually controls a plurality of blankers included in the blanker array 6. A buffer memory and data processing circuit 13 is a processing unit generating control data for the blanking control circuit 12. A deflector control circuit 14 is a control circuit controlling a plurality of deflectors included in the deflector array 8 with a common signal. A stage control circuit 15 controls positioning of the stage 11 in cooperation with a laser interferometer (not illustrated), which measures position of the stage 11.

A pattern data memory 16 stores pattern data to be drawn on a shot (i.e., design pattern data or simply pattern data). A data conversion calculator 17 divides pattern data into stripe units having a width set by the drawing apparatus and then converts the pattern data to multi-valued intermediate data. An intermediate data memory 18 stores the intermediate data. A main control unit 19 transfers the intermediate data to the buffer memory of the buffer memory and data processing circuit 13 according to a pattern to be drawn, and comprehensively controls the drawing apparatus by the control of the plurality of control circuits and the processing circuit. In this exemplary embodiment, a control unit of the drawing apparatus includes the components 12 to 18 and the main control unit 19. However, this is merely an example and may be appropriately modified.

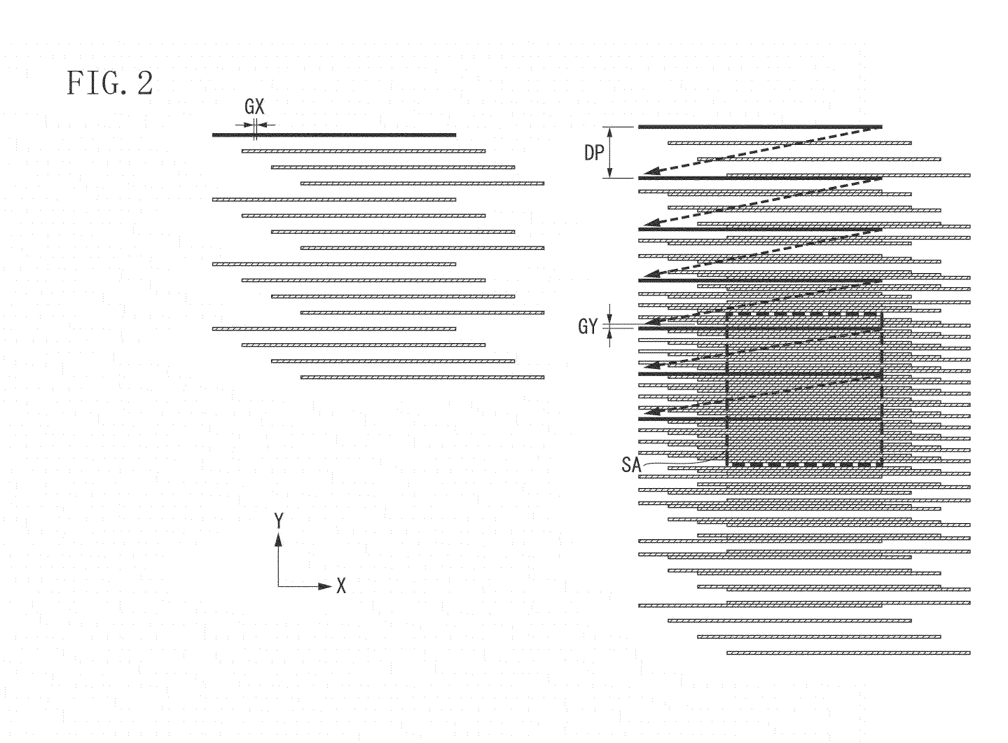

A raster scanning drawing method according to this exemplary embodiment will be described with reference to FIG. 2. An electron beam raster-scans on a scan grid on the wafer 10, which is determined by deflection of the deflector array 8 and the position of the stage 11. At the same time, the blanker array 6 controls illumination or non-illumination onto the substrate according to binary pattern data and a stripe drawing area SA having a stripe width SW of 2 μm is drawn. FIG. 2 illustrates an example of loci on the wafer 10 at scanning of electron beams arranged in four rows and four columns. In FIG. 2, the left half illustrates scanning (main scanning) loci of each electron beam of the sub array by an X direction deflector array. Here, illumination or non-illumination of each electron beam is controlled for each grid point (pixel) specified by a grid pitch GX. For ease of description, the locus of a topmost electron beam is illustrated by thick black line. In FIG. 2, the right half illustrates loci formed by each electron beam, which is sequentially repeating the scanning in the X direction through a flyback (return deflection) in the deflection width DP in a Y direction illustrated by dashed line arrows after the scanning of the each electron beam in the X direction. It is recognized that, in an area surrounded by a thick dashed line in FIG. 2, a stripe drawing area SA of the stripe width SW is filled with the grid pitches GY.

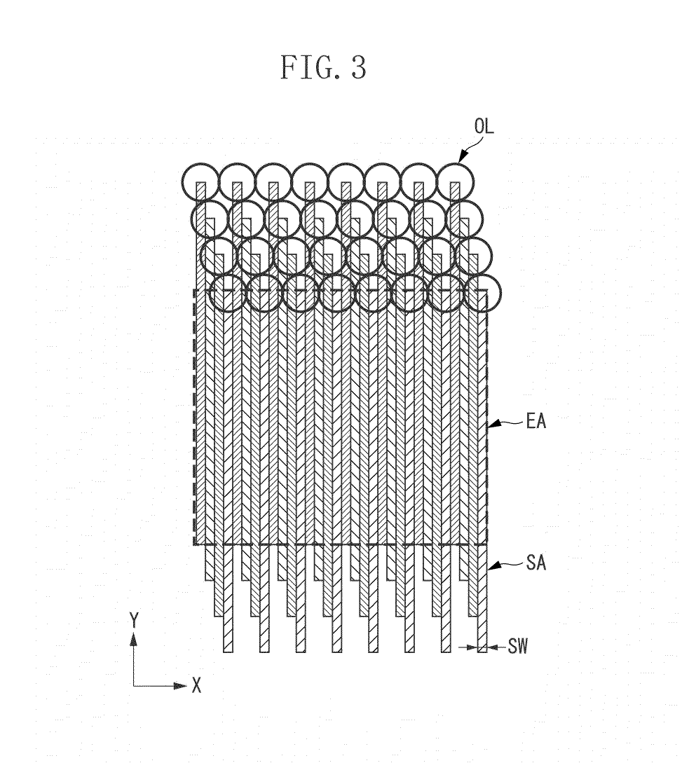

FIG. 3 is a view for illustrating a positional relationship among a plurality of stripe drawing areas SA corresponding to the respective objective lenses OL. The objective lens array 9 arranges the objective lenses OL in one dimension at the 130 μm pitches in the X direction. The objective lenses of the next row are displaced by 2 μm in the X direction such that the stripe drawing areas SA adjoin one another. For ease of illustration, in FIG. 3, the objective lens array has objective lenses arranged in four rows and eight columns. However, the objective lens array may actually have objective lenses arranged, for example, in 65 rows and 200 columns (including 13,000 objective lenses in all). With this configuration, drawing may be performed in an exposed area EA (length in X direction is 26 mm) on the wafer 10 by continuously moving the stage 11 (i.e., sub scanning) in one direction (i.e., a sub scan direction) along the Y direction. That is, the sub scanning in one direction can draw in a normal shot area (26 mm×33 mm), for example.

FIG. 4 illustrates a configuration example of a drive circuit of the blanker array 6. Control signals from the blanking control circuit 12 is supplied to the blanker array 6 via optical fibers (not illustrated) for optical communication. Control signals for the plurality of blankers included in one sub array are transmitted through one optical fiber. A light signal from the optical fiber for optical communication is received by a photo diode 61, current-voltage conversion is performed by a transfer impedance amplifier 62, and amplitude is adjusted by a limiting amplifier 63. An amplitude-adjusted signal is input to a shift register 64, where a serial signal is converted into a parallel signal. FETs 67 are arranged in the vicinity of intersections of gate electrode lines that run in the transverse direction and source electrode lines that run in the vertical direction. Two buses are respectively connected to a gate and a source of each of the FETs 67. A blanker electrode 69 and a capacitor 68 are connected in parallel to a drain of each of the FETs 67. Opposite sides of these two capacitive elements are connected to a common electrode. When voltage is applied to a gate electrode line, all the FETs 67 of one row connected to the gate electrode line are turned on and then current flows between the sources and the drains. Each voltage applied to each of the source electrode lines at that time is applied to the corresponding blanker electrode 69, and electric charge corresponding to the voltage is accumulated (i.e., charged) in the corresponding capacitor 68. When charging of all the condensers on one row is finished, the gate electrode line to which the voltage is applied is switched to a next row. Then, the FETs 67 of the first row lose the gate voltage and are turned OFF. Although the blanker electrodes 69 of the first one row lose voltage from the source electrode lines, the blanker electrodes 69 may maintain necessary voltage by the electric charge accumulated in the capacitors 68 until voltage is applied to the gate electrode lines next time. In such the active matrix driving system using FETs 67 as switches, voltage may be applied to multiple blankers in parallel by a gate electrode line and a source electrode line. Thus, it is possible to increase the number of the blankers with a less number of wirings.

In the example of FIG. 4, the blankers are arranged in four rows and four columns. The parallel signals from the shift register 64 are applied to source electrodes of the FETs 67 as voltage via a data driver 65 and the source electrode lines. In cooperation with this voltage application, the FETs 67 of one row are turned on by the voltage applied from the gate driver 66, and thereby the corresponding blankers of the row (Data set unit) are controlled. Such an operation is sequentially repeated for the each row and thus the blankers arranged in four rows and four columns are controlled.

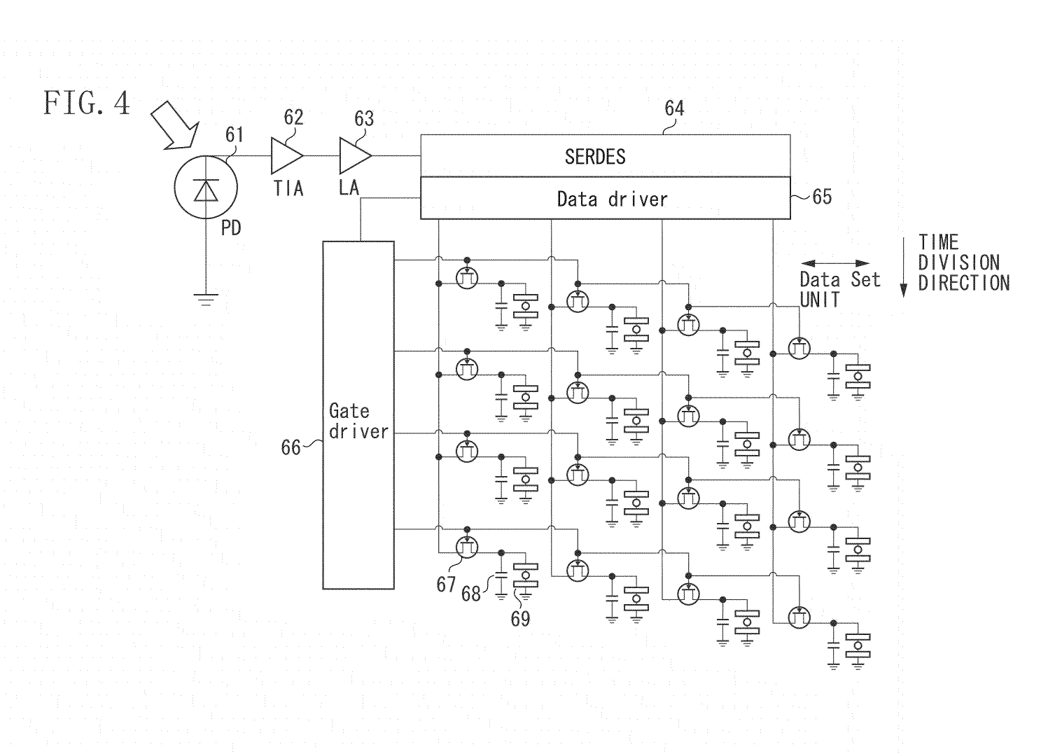

FIG. 5 illustrates another configuration example of a drive circuit of the blanker array 6. In FIG. 5, components similar to the components in FIG. 4 are denoted by the same reference numerals and description thereof will not be repeated. A point different from the configuration example of FIG. 4 is that the arrangements (wirings) of the gate driver (gate electrode lines) and data driver (source electrode lines) are switched with respect to blankers (beams) arranged in four rows and four columns. The control method of each of the blankers is similar to that for the configuration in FIG. 4 and they are not essentially different. In this exemplary embodiment, the terms: “row” and “column” are not particularly distinguishable, and both of them can be referred to as “row” or “column”. In FIGS. 4 and 5, at least components 64 to 67 are included in a drive circuit that sequentially drives the column units of blanker array 6 one by one periodically.

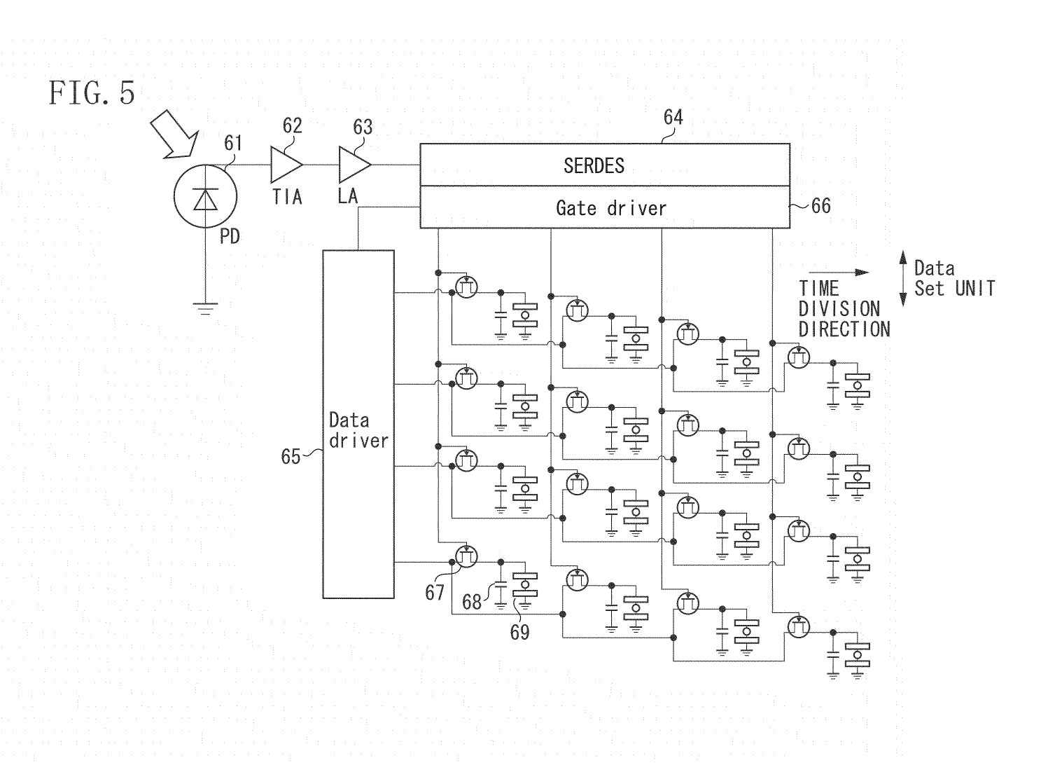

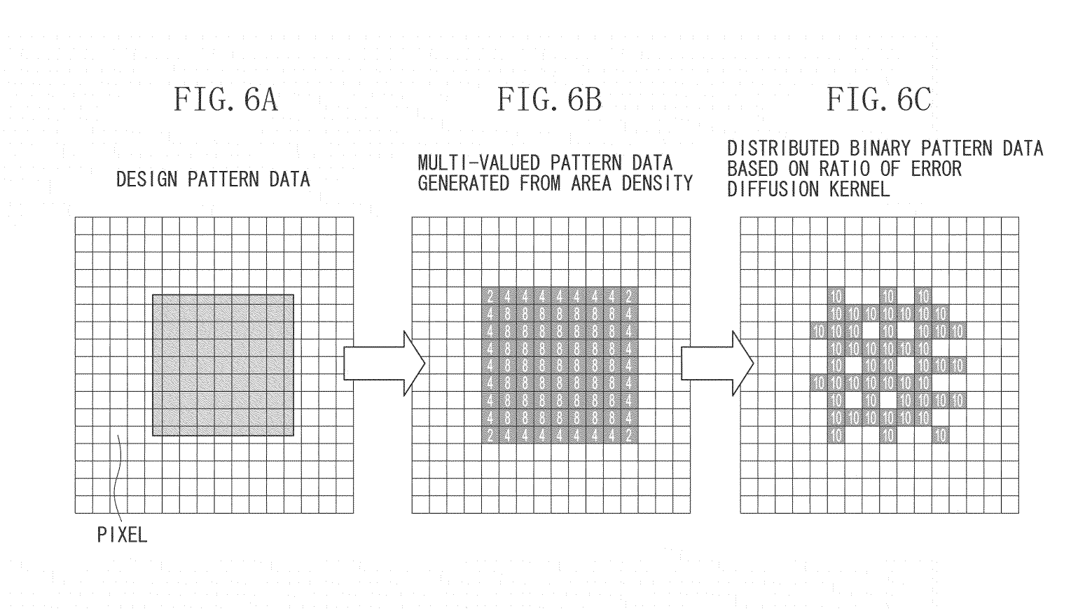

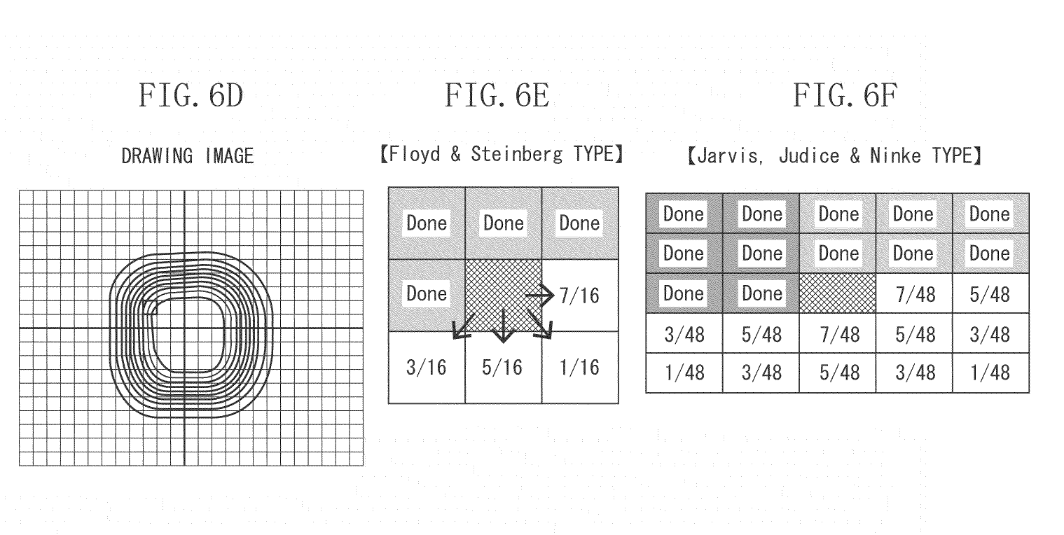

FIGS. 6A, 6B, 6C, 6D, 6E, and 6F illustrate the drawing method of spatial modulation system. FIG. 6A illustrates design pattern data arranged on the scanning grid (i.e., pixels) of the drawing apparatus. The pattern data is square pattern data of 20 nm×20 nm designed on grid points (pixels) of 0.25 nm pitches. In the scanning grid, the pitch between the grid points is 2.5 nm. Since the pitch of the design grid is less than the pitch of the scanning grid, the pattern data cannot be accurately drawn on the scanning grid as illustrated in FIG. 6A. Therefore, area densities of the pattern data on the respective grid points (pixels) are calculated as illustrated in FIG. 6B. Based on the area densities, amounts of exposure (dose) of the respective grid points are calculated, and multi-valued pattern data is generated. In FIG. 6B, an amount of exposure of a beam per a grid point is set to ten and an amount of exposure of the pattern data per a grid point is set to eight. In order to represent pattern data by coarseness and fineness of grid points (amount of exposure is ten) where a beam is turned on, the multi-valued pattern data is converted to binary pattern data by using an error diffusion method. Binarization using a kernel of Floyd & Steinberg type error diffusion method illustrated in FIG. 6E is performed here. However, another kernel such as a kernel of Jarvis, Judice & Ninke type illustrated in FIG. 6F may be used.

More specifically, for the grids of the multi-valued pattern data illustrated in FIG. 6B, when a value of each of the grid points is less than five, the value of the grid point is set to zero, and when the value is five or more, the value of the grid point is set to ten. Then, an error between the set value and an original value is distributed to the surrounding grid points at a ratio determined by the error diffusion kernel illustrated in FIG. 6E. The processing is repeated from the grid point at the upper left to the grid point at the lower right in the order of raster scanning. The result is illustrated in FIG. 6C. Then, an image drawn by controlling beams based on the binary pattern data of FIG. 6C is illustrated in FIG. 6D. In this exemplary embodiment, the beam diameter is set to be sufficiently large comparing to the grid point of 2.5 nm×2.5 nm, and coarseness and fineness pattern on the grid is smoothed.

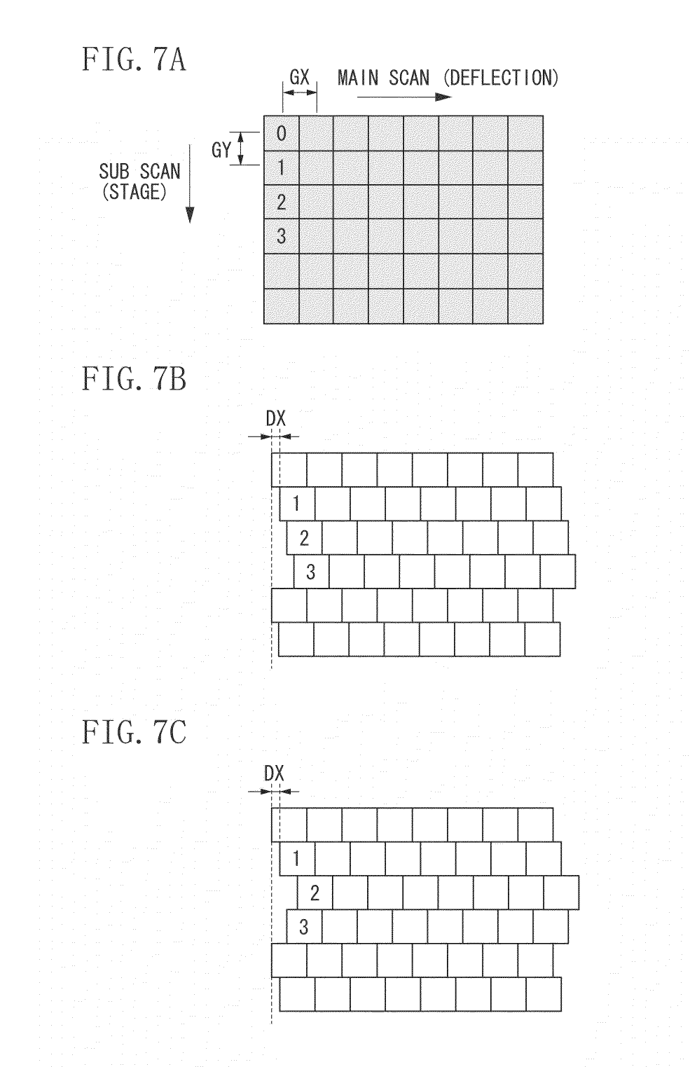

FIGS. 7A, 7B, and 7C illustrate an example of arranging scanning grid (pixels) when the blanker array 6 is driven. FIG. 7A illustrates a scanning grid (first grid) according to the design of the drawing apparatus, and FIGS. 7B and 7C illustrate actual scanning grids (second grid) determined by driving the blanker array 6. With either configurations of the blanker arrays of FIG. 4 or 5, positional deviation (i.e., displacement) DX in the main scan direction is generated with respect to the scanning grid of the design of FIG. 7A depending on gate drive timing of the scanning grid. An amount of positional deviation DX between arbitrary adjacent two rows can be determined depending on at least one of a circuit configuration of the blanker array, the number of the gate electrodes, a delay time for sequentially driving gates, a flyback deflection width of the deflector array 8, and a deflection speed of the deflector array 8. The amount of positional deviation DX is not necessarily constant between arbitrary adjacent two rows, and a configuration in which the amount changes as illustrated in FIG. 6C is possible.

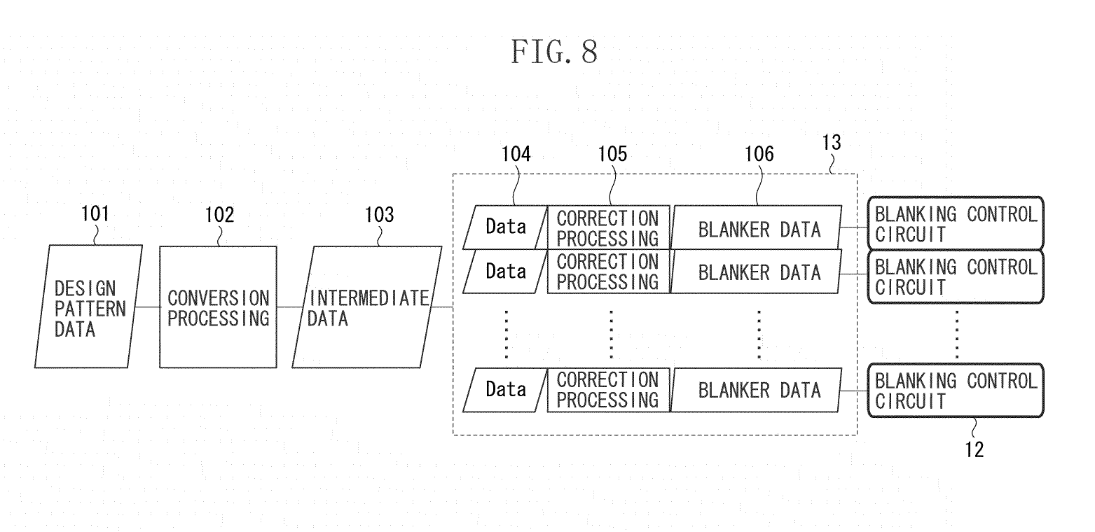

FIG. 8 illustrates a data flow of the drawing apparatus of this exemplary embodiment. Design pattern data 101 is vector graphics pattern data (i.e., pattern data corresponding to a shot within 26 mm×33 mm) stored in the pattern data memory 16. Conversion processing 102 is performed by the data conversion calculator 17 and may include preparation processing to be described next.

Preparation Processing

First, optical proximity correction is performed on the design pattern data 101. At this time, gradations of the pattern data may be changed. The data obtained by performing the optical proximity correction is divided into stripe units corresponding to the stripe drawing areas SA. In this exemplary embodiment, stitching is performed by double drawing (double exposure) using adjacent beams. Thus, overlapping areas having a width of 0.1 μm are added to both sides to generate intermediate stripe data having a width of 2.2 μm (overlapping part of adjacent stripe data may be identical data).

Intermediate stripe data is stored in the intermediate data memory 18 as intermediate data 103. This concludes the preparation processing performed on the design pattern data. The intermediate stripe data is vector graphics data.

Multi-Value Processing

Hereinafter, a data flow after the wafer 10 is put into the drawing apparatus will be described. The main control unit 19 causes intermediate stripe data to be transferred from the intermediate data memory 18 to the buffer memory and data processing circuit 13. The buffer memory and data processing circuit 13 stores the transferred intermediate stripe data as multi-valued data (DATA) in stripe units. Here, intermediate stripe data of the vector graphics is converted to multi-valued pattern data on a grid (pixel) coordinate system of the drawing apparatus. More specifically, for example, the conversion may be performed based on an area density of the intermediate stripe data on each grid point, a correction coefficient based on intensity of beams drawing each stripe, and dose (i.e., an amount of exposure) correction coefficient (basically 0.5) in a double drawing area.

Correction Processing

The buffer memory and data processing circuit 13 performs correction processing 105 on multi-valued pattern data in each stripe in parallel to drawing. The processing includes coordinate transformation, binarization processing, and serial data conversion to be described later.

Coordinate Transformation

Since the drawing is performed to overlap with a shot on the wafer 10, coordinate transformation is performed using the following equation based on information required for calculating shot arrangement on the wafer 10, which is previously measured (for example, expansion and contraction coefficient (magnification coefficient) βr, rotation coefficient er, and translation coefficient Ox, Oy).

$$( \begin{matrix}{x}^{′} \\ {y}^{′}\end{matrix} ) = ( \begin{matrix}Ox \\ Oy\end{matrix} ) + ( \begin{matrix}1 + β r & 0 \\ 0 & 1 + β r \end{matrix} ) ( \begin{matrix}1 & - θ r \\ θ r & 1\end{matrix} ) ( \begin{matrix}x \\ y\end{matrix} ) \qquad ( 1 )$$

In the equation, x and y are coordinates of multi-valued pattern data for each of the stripes before the correction, and x′ and y′ are coordinates of multi-valued pattern data for the each stripe after the correction. Ox and Oy may include offset amounts for correcting positional deviation from a designed position of electron beams corresponding to the stripe.

Binarization Processing

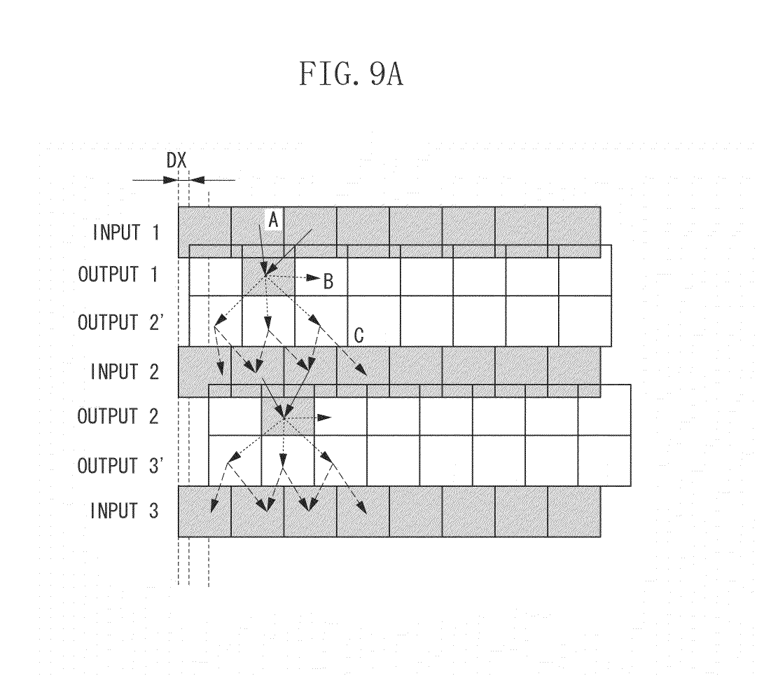

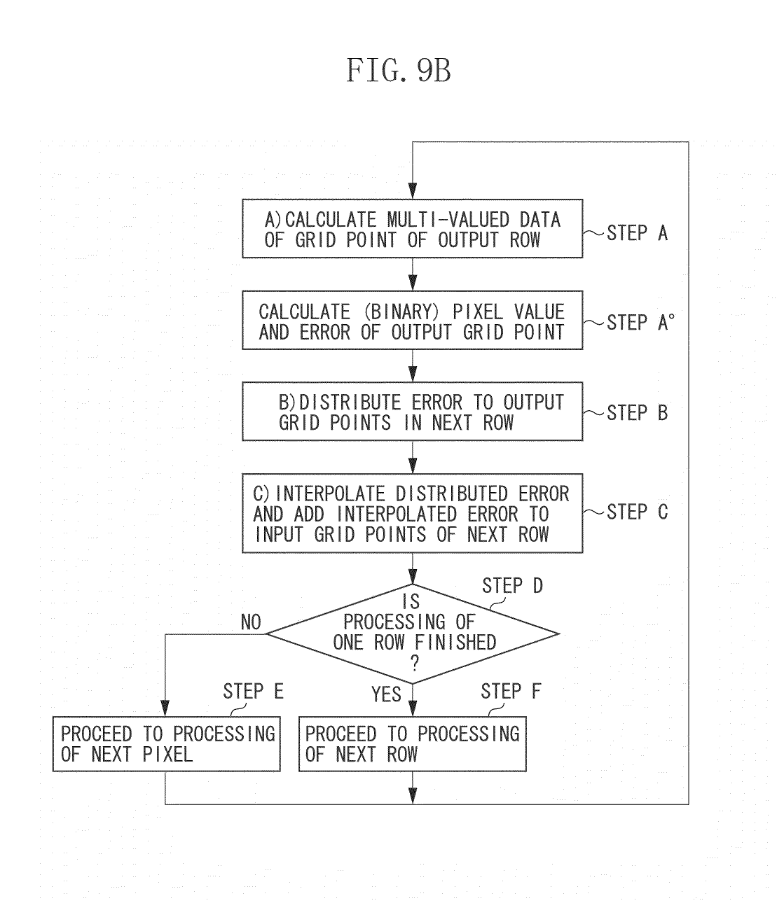

Processing of converting the multi-valued pattern data after the coordinate transformation to binary stripe pattern data (i.e., on/off signals for beams) using Floyd & Steinberg type error diffusion method will be described with reference to FIGS. 9A and 9B. The processing includes repeated processing of each of the grid points (i.e., pixels) and of each of the rows in the order of drawing. Thus, the processing will be described with emphasis on processing of one grid point. As illustrated in FIG. 9A, a grid to be input to the processing is the grid (i.e., the first grid) that has been described with reference to FIG. 7A. A grid to be output is a scanning grid (i.e., a second grid) that is determined by driving the active matrix of the blanker array as described with reference to FIG. 7B or 7C.

Multi-valued data (also referred to as second image data) of a grid point (i.e., a pixel) n of a row of output 1 is calculated from grid point values (i.e., pixel values which are also referred to as first image data) of a row of corresponding input 1 by interpolation processing in Step A of a flow chart illustrated in FIG. 9B. More specifically, a value at the output grid point can be calculated by the following equation:

output 1(n)=input 1(n)×(1−dx)+input 1(n+1)×dx,

where dx is a ratio of an amount of positional deviation DX between the input grid and the output grid to the grid pitch GX. When dose (amount of exposure) control of time modulation is performed, the value of the output grid point can be used as blanker data without performing the following processing. When dose control of spatial modulation system is performed on the other hand, the value of the output grid point is binarized by error diffusion processing. First, in Step A°, binarization is performed and an error introduced by the binarization is calculated. In Step B, The error introduced by the binarization is distributed to the surrounding grid points using the error diffusion kernel of FIG. 6E. At this time, the error distribution to a next row is performed on a virtual row of output 2′ having grid arrangement corresponding to grid arrangement of output 1 because square or rectangle grid arrangement is assumed for the error diffusion kernel of FIG. 6E.

In Step C, the error distributed to grid points of the row of output 2′ is interpolated based on an amount of positional deviation DX of the grid between the row of output 2′ and the row of input 2 and then added to grid points of the row of INPUT 2. The value obtained by the addition is used for binarization processing of the row of input 2.

In Steps D and E, The above-described processing is performed sequentially on the respective grid points in a row and, in Steps D and F, the whole processing is repeated for the respective rows. Thus, blanker data, in which positional deviation between the designed scanning grid (i.e., the first grid) and the actual scanning grid (i.e., the second grid) is compensated, is generated. Therefore, positional deviation or a blur (thinning of a line width, for example) in a drawn pattern can be reduced, and thus it is possible to provide a drawing apparatus having an advantage of accurate drawing with respect to drawing data (i.e. the design pattern data). In addition, this exemplary embodiment can be realized by merely adding components for performing simple processing regarding error diffusion processing including A) processing for distributing (i.e., interpolating) input data to grid points of an output row, and C) processing for distributing an error to grid points of a next input row. Therefore, increase in manufacturing cost of a drawing apparatus can be suppressed low.

Further, the distribution ratio dx can be determined based on beam arrangement error due to such as manufacturing error of the pattern aperture array 5 as well as the positional deviation DX due to deviation of timing of driving gates in the blanker array. Thus, the accuracy of drawing can be further improved. The binarization processing is performed at the final stage of the correction processing. At the same time, compensation of positional deviation of the scanning grid caused by driving the active matrix is performed. Therefore, data in processing at stages before the final stage can be handled as general data that does not depend on a configuration of the blanker array. Therefore, only the binarization processing needs to be changed when the configuration of the blanker array is changed.

Serial Data Conversion

Next, data binarized for each beam is sorted in the order of drawing to generate blanker data 106. The generated blanker data 106 is serially transferred to the blanking control circuit 12, and the blanking control circuit 12 converts the transferred blanker data 106 to a control signal corresponding to the blanker array 6. The control signal is supplied to the blanker array 6 via an optical fiber for optical communication (not illustrated).

As described above, in this exemplary embodiment, blanker data is generate while interpolating design pattern data, so that increase in manufacturing cost and increase in volume of a drawing apparatus can be suppressed. Thus, a drawing apparatus having an advantage of accurate drawing with respect to drawing data (i.e., the design pattern data) can be provided while the active matrix driving system is employed for a blanker array.

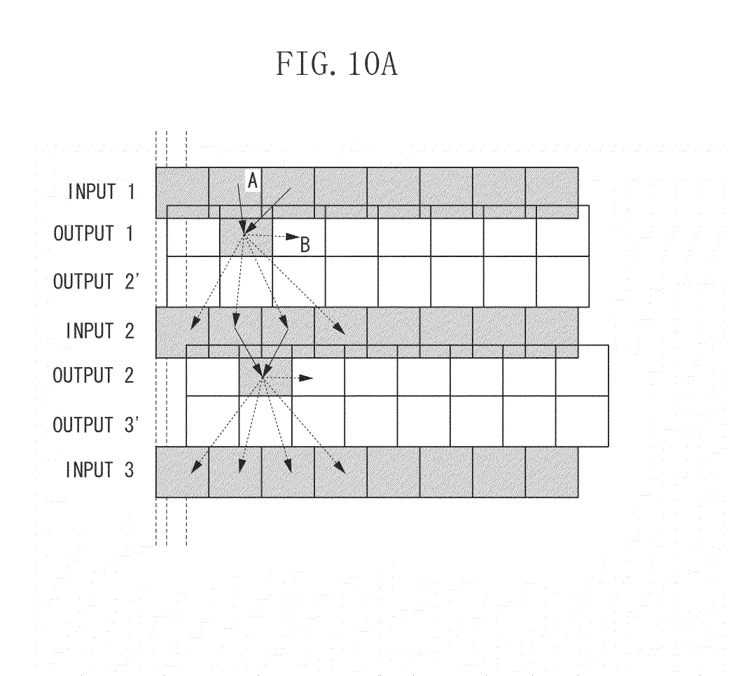

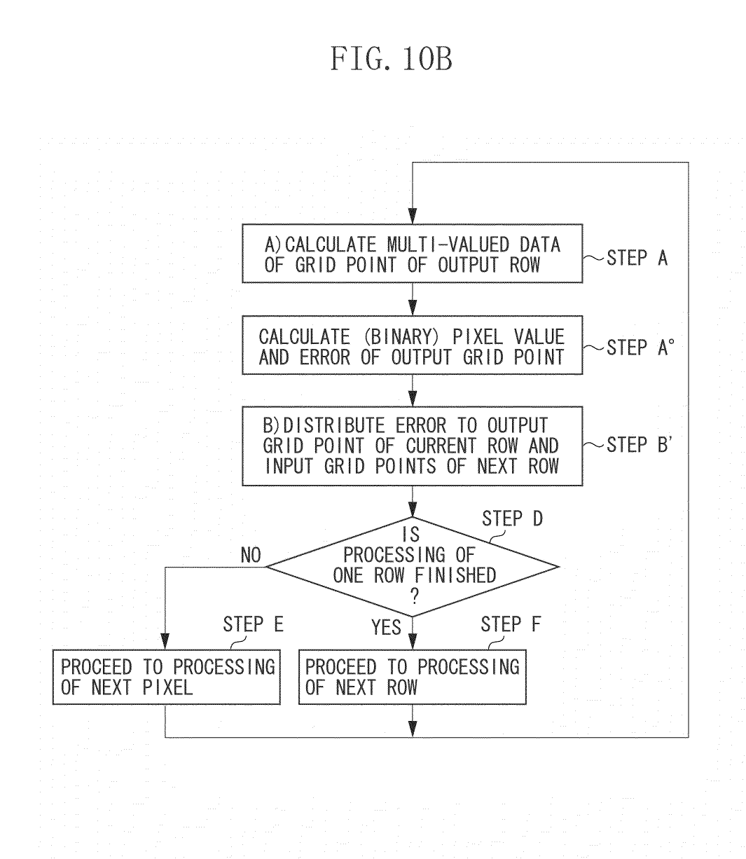

A second exemplary embodiment is different from the first exemplary embodiment in detail of the binarization processing. Binarization processing of this exemplary embodiment will be described with reference to FIGS. 10A and 10B. Description of matters that are common to the first exemplary embodiment will not be repeated.

Multi-valued data (also referred to as second image data) of a grid point (i.e., a pixel) n of a row of output 1 is calculated from grid point values (i.e., pixel values which are also referred to as first image data) of a row of corresponding input 1 by interpolation processing. More specifically, a value at the output grid point can be calculated by the following equation:

output 1(n)=input 1(n)×(1−dx)+input 1(n+1)×dx,

where dx is a ratio of an amount of positional deviation DX between the input grid and the output grid to the grid pitch GX. When dose control of spatial modulation system is performed, the multi value of the output grid point is binarized by error diffusion processing. The error introduced by the binarization is distributed to the surrounding grid points. At this time, error distribution to grid points of a next row is directly performed to the row of input 2. As an error diffusion kernel used for the error distribution, a kernel obtained based on the kernel of FIG. 6E and a distribute ratio dx corresponding to an amount of positional deviation DX of the grid between the row of output 1 and the row of input 2.

In the second exemplary embodiment, Steps B and C of the binarization processing in the first exemplary embodiment are combined into one step (Step B′ of a flow chart illustrated in FIG. 10B). Therefore, an intermediate buffer for output 2′ can be eliminated and a calculation amount can be reduced. When different amounts of positional deviation DX between rows exist as a case illustrated in FIG. 7C, different error diffusion kernels have to be used. In addition, the size of the error diffusion kernels is increased because of the increase of the number of grid points to which error is diffused (distributed).

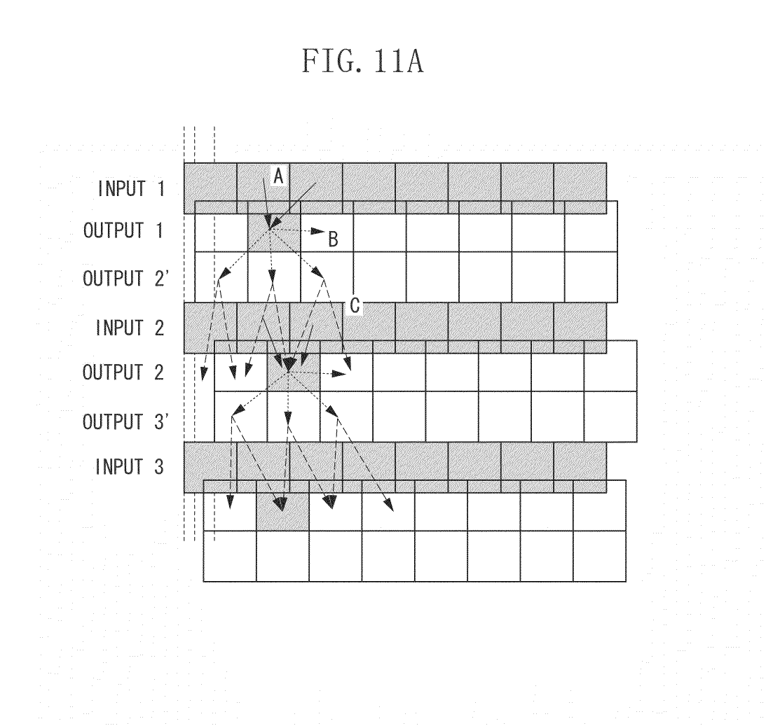

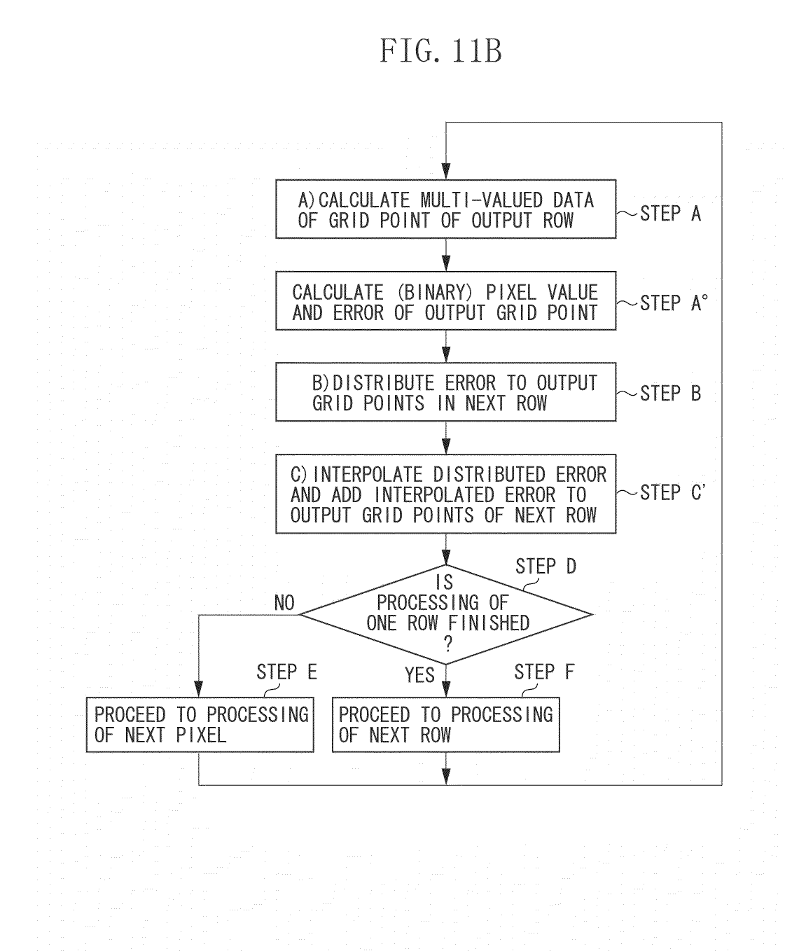

A third exemplary embodiment is different from the first exemplary embodiment in detail of the binarization processing. Binarization processing of this exemplary embodiment will be described with reference to FIGS. 11A and 11B. Description of matters that are common to the first exemplary embodiment will not be repeated.

Multi-valued data (also referred to as second image data) of a grid point (i.e., a pixel) n of a row of output 1 is calculated from grid point values (i.e., pixel values which are also referred to as first image data) of a row of corresponding input 1 by interpolation processing. More specifically, a value at the output grid point can be calculated by the following equation:

output 1(n)=input 1(n)×(1−dx)+input 1(n+1)×dx+output 1(n),

where dx is a ratio of an amount of positional deviation DX between the input grid and the output grid to the grid pitch GX. At this time, in grid points of the row of OUTPUT 1, errors diffused in processing of the previous row are previously input as initial values (i.e., the last term of the above equation). When dose control of spatial modulation system is performed, the multi value of the output grid point is binarized by error diffusion processing. The error introduced by the binarization is distributed to the surrounding grid points by using the error diffusion kernel of FIG. 6E. At this time, the error distribution to grid points of a next row is performed on a virtual row of output 2′ having grid arrangement corresponding to grid arrangement of output 1 because square or rectangle grid arrangement is assumed for the error diffusion kernel of FIG. 6E. The error distributed to grid points of the row of output 2′ is interpolated based on a difference ΔDX between amounts of positional deviation of the grid of the row of OUTPUT 1 and the row of OUTPUT 2 and then added to grid points of the row of output 2 in Step C′ of a flowchart of FIG. 11B.

This exemplary embodiment is different from the exemplary embodiment 1 in that the error introduced by the binarization processing is diffused to output grid points instead of input grid points. In the exemplary embodiment 1, the error is diffused to input grid points of the next row. Thus, the next row cannot be processed until the input grid points of the next row are read. In this exemplary embodiment on the other hand, the error is previously diffused to the output grid points. Thus, the processing of the next row can be immediately started.

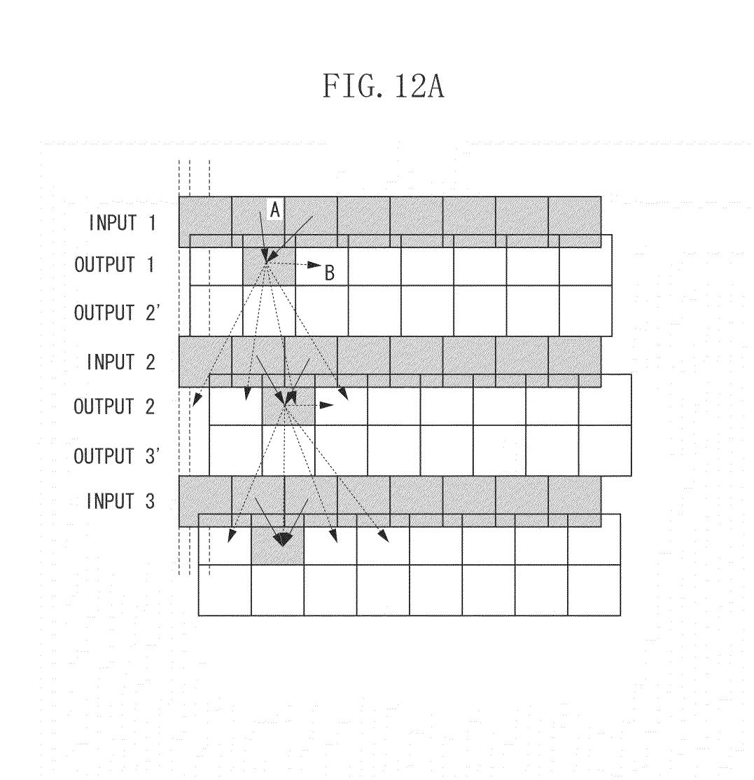

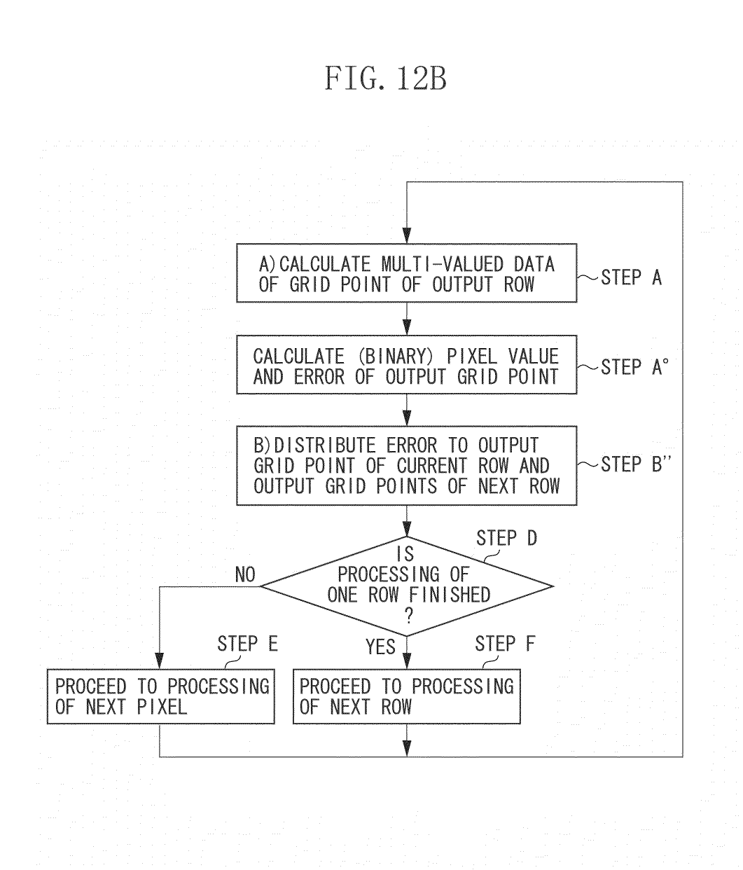

A fourth exemplary embodiment is different from the third exemplary embodiment in detail of the binarization processing. Binarization processing of this exemplary embodiment will be described with reference to FIGS. 12A and 12B. Description of matters that are common to the third exemplary embodiment will not be repeated.

Multi-valued data (also referred to as second image data) of a grid point (i.e., a pixel) n of a row of output 1 is calculated from grid point values (i.e., pixel values which are also referred to as the first image data) of a row of corresponding input 1 by interpolation processing. More specifically, a value at the output grid point can be calculated by the following equation:

output 1(n)=input 1(n)×(1−dx)+input 1(n+1)×dx+output 1(n),

where dx is a ratio of an amount of positional deviation DX between the input grid and the output grid to the grid pitch GX. In grid points of the row of output 1, errors diffused in processing of the previous row are previously input as initial values (i.e., the last term of the above equation). When dose control of spatial modulation system is performed, the multi value of the output grid point is binarized by error diffusion processing. The error introduced by the binarization is distributed to the surrounding grid points. At this time, error distribution to a next row is performed directly on a row of output 2. For the error distribution, a kernel obtained based on the kernel of FIG. 6E and the distribute ratio dx corresponding to the difference ADX between the amounts of positional deviation of the grid of the row of output 1 and the row of output 2 is used as an error diffusion kernel.

In this exemplary embodiment, Steps B and C′ of the binarization processing in the third exemplary embodiment are combined into one step (Step B″ of a flowchart illustrated in FIG. 12B). Therefore, an intermediate buffer for output 2′ can be eliminated and a computation amount can be reduced. When different amounts of positional deviation DX between rows exist as a case illustrated in FIG. 7C, different error diffusion kernels have to be used. In addition, the size of the error diffusion kernels is increased because of the increase of the number of grid points to which error is diffused (distributed).

A method for manufacturing an article according to a fifth exemplary embodiment is suitable to manufacture articles including micro devices such as semiconductor devices, and elements having a microstructure. The manufacturing method may include forming a latent image pattern on a photosensitive agent applied to a substrate using the drawing apparatus (i.e., performing drawing on the substrate) and developing the substrate on which the latent image pattern is formed. In addition, the manufacturing method may include other known processing such as oxidization, film formation, vapor deposition, doping, smoothing, etching, resist removing, dicing, bonding, and packaging. The method for manufacturing an article of this exemplary embodiment is advantageous in at least one of performance, quality, productivity, and production cost of the article as compared with those of the related art method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

In the above exemplary embodiments, linear (first order) interpolation processing is performed as the interpolation processing for compensating positional deviation between the designed scanning grid (first grid) and the actual scanning grid (second grid), but other interpolation processing can be used. Instead of the linear interpolation, interpolation processing using other interpolation functions such as interpolation processing using a higher order polynomial and spline interpolation processing can be performed.

This application claims the benefit of Japanese Patent Application No. 2012-263514 filed Nov. 30, 2012, which is hereby incorporated by reference herein in its entirety.

What is claimed is:

1. A drawing apparatus that performs drawing on a substrate with a plurality of charged particle beams based on first image data associated with a first grid, the apparatus comprising:
a blanker array including a plurality of columns each including a plurality of blankers;
a scanning deflector configured to deflect at least one of the charged particle beams that has not been blanked by the blanker array to cause the deflected beam to scan the substrate in a scan direction;
a drive circuit configured to sequentially drive the blanker array with respect to each of the plurality of columns periodically to define a second grid on the substrate that is displaced from the first grid in the scan direction; and
a controller configured to generate second image data on the second grid by performing interpolation processing on the first image data associated with the first grid and to control the drive circuit based on the second image data.

2. The drawing apparatus according to claim 1, wherein the scanning deflector is configured to deflect the at least one of the charged particle beams in a main scan direction, and
wherein the drive circuit is configured to define the second grid that is displaced from the first grid in the main scan direction.

3. The drawing apparatus according to claim 1, further comprising:
a stage configured to hold the substrate and to be moved in a sub scan direction.

4. The drawing apparatus according to claim 1, wherein the controller is further configured to perform error diffusion processing on the second image data.

5. The drawing apparatus according to claim 4, wherein the controller is configured to generate errors to be diffused to grid points of a row of the first grid, which is next to a row of a grid point on the second grid on which the errors are generated by the error diffusion processing, and to diffuse the generated errors to the first image data corresponding thereto.

6. The drawing apparatus according to claim 4, wherein the controller is configured to generate errors to be diffused to grid points of a row of the second grid, which is next to a row of a grid point on the second grid on which the errors are generated by the error diffusion processing, and to diffuse the generated errors to the second image data corresponding thereto.

7. The drawing apparatus according to claim 5, wherein the controller is configured to generate the errors to be diffused to the grid points of the next row of the first grid by performing interpolation processing on errors that have been diffused on the second grid via the error diffusion processing on the second image data.

8. The drawing apparatus according to claim 6, wherein the controller is configured to generate the errors to be diffused to the grid points of the next row of the second grid by performing interpolation processing on the errors that have been diffused on the second grid via the error diffusion processing on the second image data.

9. A method for manufacturing an article, the method comprising:
performing drawing on a substrate using a drawing apparatus; and
developing the substrate, on which the drawing has been performed, to manufacture the article,
wherein the drawing apparatus is configured to perform drawing on the substrate with a plurality of charged particle beams based on first image data associated with a first grid, the drawing apparatus including:
a blanker array including a plurality of columns each including a plurality of blankers;
a scanning deflector configured to deflect at least one of the charged particle beams that has not been blanked by the blanker array to cause the deflected beam to scan the substrate in a scan direction;
a drive circuit configured to sequentially drive the blanker array with respect to each of the plurality of columns periodically to define a second grid on the substrate that is displaced from the first grid in the scan direction; and
a controller configured to generate second image data on the second grid by performing interpolation processing on the first image data associated with the first grid and to control the drive circuit based on the second image data.
